(19) United States
(12) Patent Application Publication
(10) Pub. No.: US 2006/0109948 A1
(43) Pub. Date: May 25, 2006

(54) High frequency counter circuit

(75) Inventor: Yasuhiro Hashimoto, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/153,440

(22) Filed: Jun. 16, 2005

(30) Foreign Application Priority Data
Nov. 25, 2004 (JP) 2004-340317

(51) Int. Cl. H03K 23/50

(52) U.S. Cl. 377/120

(57) ABSTRACT

The object of the present invention is to provide a counter circuit, which can be operated with a high frequency clock. In order to realize the operation with a high frequency the counter circuit comprises first counter circuit 1 and second counter circuit 2, counting input signals, and a counter output switching circuit 3, to switch the output signal of the first counter circuit 1 and the second counter circuit 2.

### FIELD OF THE INVENTION

The present invention relates to a counter circuit, which operated with high frequency clock.

### DESCRIPTION OF THE RELATED ART

From long before the counter circuit has served various uses such as counting internal signals consisting data processors.

Generally, counter circuits have two types: synchronous counter circuits and asynchronous counter circuits. These two types are used as appropriate, however both circuits comprise a plurality of flip-flops such as RS flip-flops and D flip-flops.

FIG. 1A is a diagram describing an example of the configuration of a conventional asynchronous 8-bit counter circuit.

The counter circuit shown in FIG. 1A has macros (X00 through X07), comprising D flip-flops and inverters, connected in series. When the clock signal is applied to the clock input terminal CK, the macro X00 outputs (latches) the signal with a frequency twice that of the input signal according to the change in the rising edge of the input signal, to an output terminal DA. In a similar way, macros, which receive the input of the output signal of any one macro, output (latch) the signal with a frequency twice that of the input signal to the output terminal DA.

The count value of the clock signal can be obtained by extracting the signal, latched by the output terminal DA of the each macro, from the output terminals D0 through D7. In such a case, the output terminal D0 is the LSB and the output terminal X07 is the MSB.

FIG. 1B is a diagram describing an example of the configuration of a conventional synchronous 12-bit counter circuit.

The counter circuit shown in FIG. 1B has macros (X00 through X11), comprising a D flip-flop, AND circuit and EOR circuit shown in FIG. 12, connected in series. When the clock signal is applied to the clock input terminal CK, the macro X00 outputs (latches) the signal with a frequency twice that of the input signal according to the change in the rising edge of the input signal. At the same time, the signal, output CO from the preceding macro and the output of the D flip-flop of current macro are ANDed, output from the output terminal CO, and input to the following macro. By so doing, a carry up process is performed.

The count value of the clock signal can be obtained by extracting the signal, latched by the output terminal DA of the each macro. In such a case, the D flip-flop X00 is the LSB and the D flip-flop X07 is the MSB.

Japanese Published Unexamined Application No. 2003-121499 describes a counter circuit, used to reduce the performance time of an integration test, utilizing a decode circuit, without increasing the test data volume.

However, the above explained counter circuit has the technical issue that on attempting to increase the clock frequency of the counter, as shown in FIG. 1A and FIG. 1B, carry time lag (transmission time lag) occurs when the output of any one macro is transmitted to the macro following any one macro, and consequently causes malfunction.

There is another issue that on increasing the bit number of the counter, malfunction is caused because the carry time lag is increased in proportion to the bit number.

### SUMMARY OF THE INVENTION

The present invention is created reflecting the above issues. It is an object of the present invention to provide a counter circuit, which can be operated at a high clock frequency.

In order to achieve the above object, the counter circuit relating to the present invention comprises a plurality of count units, which count the input signal and output the count result, a phase control unit, which controls a plurality of the count units so that they comprise a designated phase difference between each other, and a counter output switching unit, which switches from the output of any one count unit, controlled to comprise a designated phase difference by the phase control unit, to the output of the count units, comprising a leading phase of the count unit.

The counter circuit relating to the present invention can be a counter circuit comprising a first counter circuit, which counts the input signal and outputs the count result, a second counter circuit, which counts the input signal and outputs the count result, a phase control circuit, which controls the phase so that the second counter circuit has a phase difference of π [rad] from the first counter circuit, and a counter output switching unit, which switches between the output of the first counter circuit to the output of the second counter circuit, comprising a leading phase of π [rad] from the first counter circuit by the phase control unit with designated timing.

The counter circuit relating to the present invention can also be a counter circuit comprising a first counter circuit, which counts the input signal and outputs the count result, a second counter circuit, which counts the input signal and outputs the count result, a third counter circuit, which counts the input signal and outputs the count result, a fourth counter circuit, which counts the input signal and outputs the count result, a phase control circuit, which controls the counter circuits so that each of the first and the second counter circuits, the second and the third counter circuits, the third and the fourth counter circuits, and the fourth and the first counter circuits have leading phases of π/2 [rad], a counter output switching unit, which switches the output of the first counter circuit, the second counter circuit, the third counter circuit, and the fourth counter circuit, each comprising a leading phase of π/2 [rad] by the phase control circuit with designated timing.

In the counter circuit of the present invention comprising a plurality of counter units, which count the input signal and output the counting result, counting can be a method comprising a phase control process, which controls a plurality of count units so that they have a designated phase difference from each other, a counter output switching process, which switches from the output of any one of the count units controlled to have a designated phase difference by the phase control process to the output of the count units of the counter circuit comprising leading phase of the above count unit.

In addition, the counter circuit relating to the present invention can also be a counter circuit comprising a count unit, which counts the input signals and outputs the count results with a designated phase difference from each other, and counter output switching unit, which selects the output of any one count unit among a plurality of the count units and serially switches it to the output of the count units of the counter circuit comprising the leading phase of the above count unit at a designated timing according to the input signal.

The counter circuit relating to the present invention can be a counter circuit comprising a plurality of count units, which count the input signal and output the count result, a phase control unit, which controls the parallel distribution process in which the input signal is provided to a plurality of the count units so that a plurality of the count units comprises a designated phase difference from each other and also controls the count process in which all count units except for a particular count unit count the value to be output after the count result while the above count unit outputs the count result, and a counter output switching unit, which switches the output from the output of the above count unit have a designated phase difference by the phase control unit, to that of the output of the count units comprising a leading phase of the above count unit.

### BRIEF DESCRIPTION OF THE DRAWINGS

FIG. 1A is a diagram describing an example of the configuration of a conventional asynchronous 8-bit counter circuit, comprised of eight of D flip-flops;

FIG. 1B is a diagram describing an example of the configuration of a conventional synchronous 12-bit counter circuit, comprised of twelve of D flip-flops;

FIG. 1C is a diagram showing a configuration of the first embodiment relating to the present invention;

FIG. 2 is a diagram showing a configuration of the HA macro used in the first embodiment;

FIG. 3 is a diagram showing a configuration of the FA macro used in the first embodiment;

FIG. 4 is a diagram showing a configuration of the SW macro used in the first embodiment;

FIG. 5 is a timing chart showing some of the more important signals in the counter circuit relating to the present invention;

FIG. 6 is a diagram showing a variation in configuration of the counter circuit relating to the present invention;

FIG. 7A is a diagram showing a variation in configuration of the counter circuit relating to the first embodiment;

FIG. 7B is a diagram showing a variation in configuration of the counter circuit relating to the first embodiment;

FIG. 8 is a diagram describing the configuration of the SW macros 37a through 37l used in the counter circuit shown in FIG. 7A and FIG. 7B;

FIG. 9A is a timing chart of some of the more important signals in the example of a variation of the counter circuit relating to the first embodiment shown in FIG. 7A and FIG. 7B;

FIG. 9B is a timing chart of some of the more important signals in the example of a variation of the counter circuit relating to the first embodiment shown in FIG. 7A and FIG. 7B;

FIG. 9C is a timing chart of some of the more important signals in the example of a variation of the counter circuit relating to the first embodiment shown in FIG. 7A and FIG. 7B;

FIG. 10 is a diagram showing a configuration of the second embodiment relating to the present invention;

FIG. 11 is a timing chart showing some of the more important signals in the counter circuit relating to the second embodiment;

FIG. 12 is a diagram describing a configuration of the FA macro used in the counter circuit shown in FIG. 10;

FIG. 13 is a diagram describing a configuration of the HA macro used in the counter circuit shown in FIG. 10;

FIG. 14 is a diagram describing a configuration of the SW macro used in the counter circuit shown in FIG. 10; and

FIG. 15 is a diagram describing a configuration of a variation of the counter circuit relating to the second embodiment.

### DESCRIPTION OF THE PREFERRED EMBODIMENTS

In order to address the issues described above, the present invention comprises a plurality of count units, which count input signals and outputs the count result, a phase control unit, which controls a plurality of the count units so that they have a designated phase difference between one another, and a counter output switching unit, which switches the output of the count unit 1, controlled by the phase control unit so as to have the designated phase difference, to the output of the count units comprising a leading phase of the count unit 1.

According to the present invention, effect of delay time, generated when the count unit counts the input signals, can be reduced in such a way that the counter output switching unit switches the output of count unit 1 to the output of the count unit comprising the leading phase to count unit 1.

The present invention further comprises an output selection unit, which generates timing of sequential selection of the count unit comprising the leading phase of a plurality of the count units according to the input signal, and the counter output switching unit can switch the output of the count unit 1 to the output of the generated count unit in response to the information from the output selection unit.

In this case also, following the timing of the sequential selection of the count unit comprising leading phase of a plurality of the count units according to the input signal, a counter output switching unit switches the output of any one of the above count units to the output of the other count unit, comprising the leading phase of one count unit. Therefore, the effect of the time lag, that occurs when the count unit counts the input signal, can be reduced.

The count unit can be a counter circuit, which consists of a plurality of flip-flops. More specifically, any kind of flip-flop, which consists of a counter circuit, such as D flip-flops, RS flip-flops and JK flip-flops, can be used.

In addition, the counter circuit, which consists of a plurality of flip-flops, can be either an asynchronous counter circuit or a synchronous counter circuit.

According to the present invention, it is possible to provide a high-frequency clock counter circuit and multibit counter circuit.

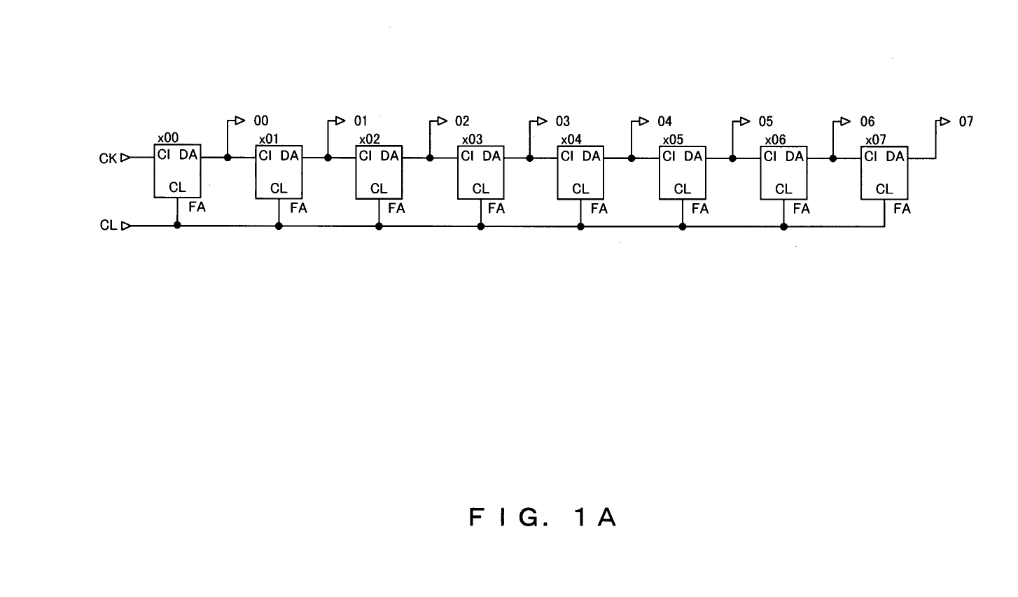

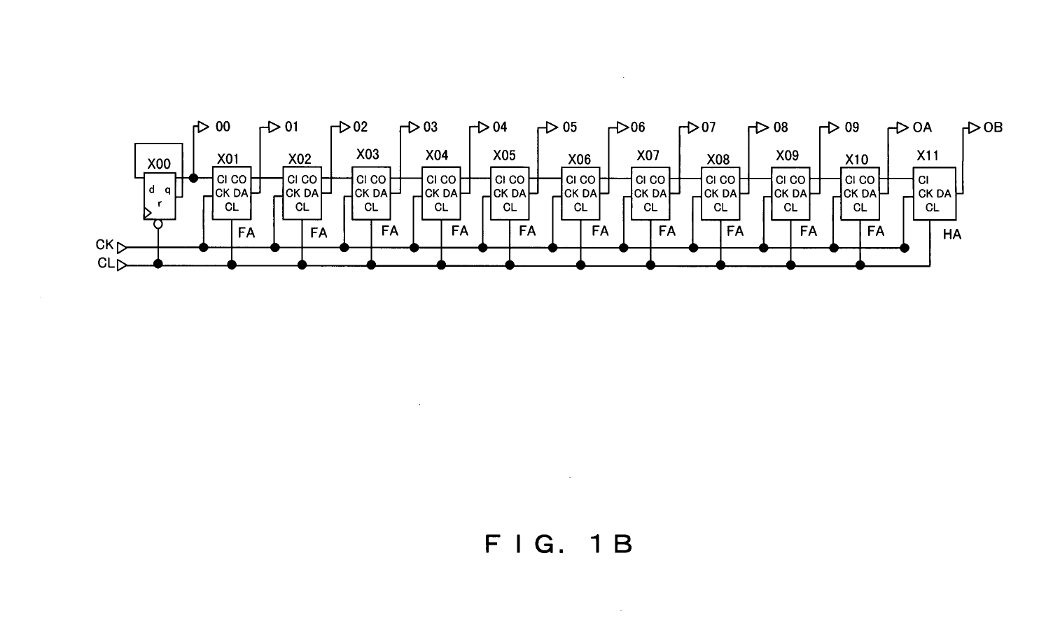

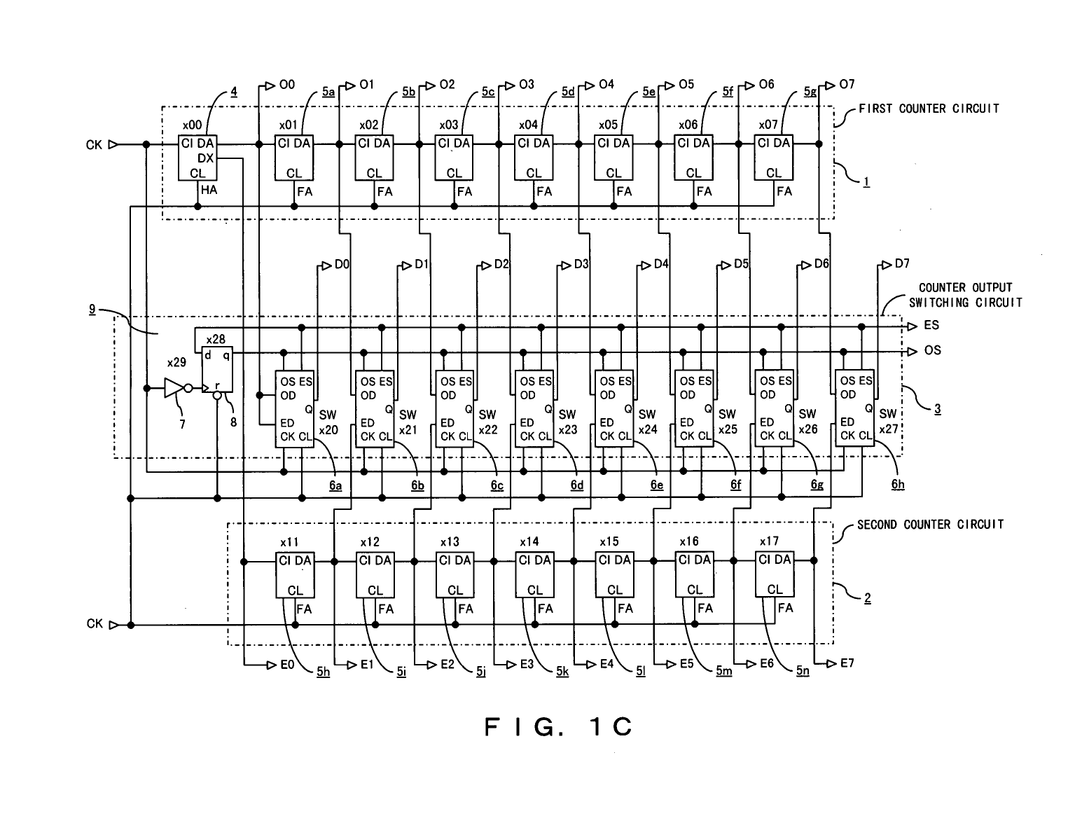

The embodiments of the present invention are hereafter explained with reference to FIG. 1C through FIG. 15.

First, an explanation of the first embodiment relating to the present invention is provided below with reference to FIG. 1C through FIG. 9C.

FIG. 1C is a diagram showing the configuration of the first embodiment relating to the present invention.

The counter circuit shown in FIG. 1C is an asynchronous circuit comprising the first counter circuit 1, counting the input signal or the clock signal, from the input terminal CK, the second counter circuit 2, counting the clock signal, which is the input signal from the input terminal CK, and the counter output switching circuit 3 for switching the output signal from the first counter circuit 1 and the output signal from the second counter circuit 2.

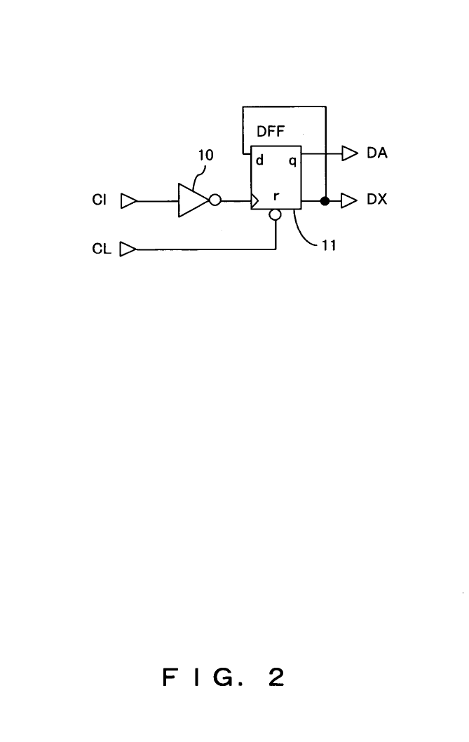

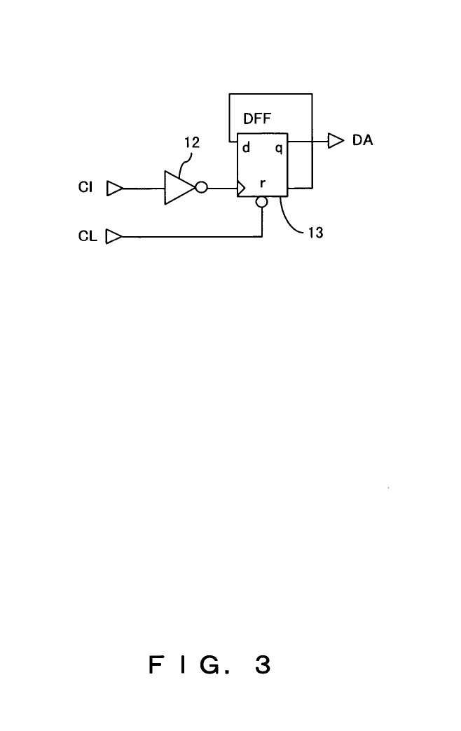

The first counter circuit 1 comprises an HA macro 4 shown is FIG. 2 and FA macros 5a˜5g shown in FIG. 3.

The clock signal with period T[s] input from the input terminal CK is provided to the input terminal CI of the HA macro 4, and the clock signal with period 2T[s] is output from the output terminal DA. The output from the HA macro 4 is sent to the input terminal CI of the FA macro 5a, and the clock signal with period 4T[s] is output from the output terminal DA followed by the input of the output signal to the input terminal CI of the FA macro 5b. In the same manner, the FA macros 5, processes the output signal of the preceding FA macro 5, that is the output signal with a period twice as short as the period of the input signal.

Here, the output signals of the HA macro 4 (the output signals from the output terminal O0) are the LSB (Least Significant Bit), and the output signals of the FA macro 5g (the output signals from the output terminal O7) are the MSB (Most Significant Bit).

The second counter circuit 2 comprises the FA macros 5h˜5n shown in FIG. 3.

In order to simplify the diagram, the second counter circuit 2 is not comprised of the HA macro 4 in FIG. 1C. However, one HA macro 4 is actually shared by two counter circuits 1 and 2.

The present invention is of the configuration in which the HA macro 4 (LSB in the counter circuit) in the first counter circuit 1 is shared by the LSB of the second counter circuit 2 for the purpose of parts sharing (i.e. circuit size-reduction). However, it is not limited to this configuration.

That is, the first counter circuit 1 and the second counter circuit 2 can comprise separate macros from LSB to MSB with dedicated HA macros and FA macros. In this case, additional circuits, a phase control circuit for controlling the phases of each counter circuit 1 and 2, and a counter output switching circuit for selecting the output signals of counter circuit 1 and 2, should be also comprised.

The clock signal with period T[s] input from the input terminal CK is provided to the input terminal CI of the HA macro 4, and the clock signal with period 2T[s] and phase difference of π [rad] is output from output terminal DX. The output from the DX of the HA macro 4 is provided to CI, that is the input terminal of the FA macro 5h, the clock signal with period 4T[s] is output from the output terminal DA, and the clock signal is provided to the input terminal CI of the FA macro 5i. Similarly, the macros 5, which input the output signal from an FA macro 5, output signals with a period twice as short as the period of the input signals.

The HA macro 4 comprises a function of phase control of the second counter circuit 2, and outputs the LSB signal of the second counter circuit 2 (the output signal from the output terminal E0). The output signal of the FA macro 5n (the output signal from the output terminal E7) is regarded as the MSB.

The counter output switching circuit 3 comprises a output selection circuit 9, comprising an inverter 7 and a D flip-flop 8, and SW macros 6a through 6h, which switch the output signals between the first counter circuit 1 and the output signal of the second counter circuit 2 in response to the output signal from the output selection circuit 9, and output to the output terminal D0 to D7.

In the output selection circuit 9, comprising the inverter 7 and the D flip-flop 8, the clock signal from the input terminal CK is provided to the D flip-flop 8 through the inverter 7. The output selection circuit 9 uses the output signal from the output terminal q as the first counter select signal (the output signal from the output terminal OS), and uses the inverted signal of the output terminal q as the second counter select signal (the output signal of the output terminal ES).

The SW macros 6a through 6h switch the output of the first counter circuit 1 and the output of the second counter circuit 2, based on the first counter select signal and the second counter select signal, and both are output from the output terminals D0˜D7. For example, the SW macro 6b outputs the output signal of the first counter circuit to the output terminal D1 when the first counter select signal is high, and outputs the output signal of the second counter circuit to the output terminal D1 when the second counter select signal is high.

The SW macro 6a relating to the present invention is configured to select the output signals of the first counter circuit 1 all of the time to simplify circuit configuration.

From the input terminal CL, the reset signal is input, and when the input signal is low, the state of the D flip-flop, which the first counter circuit 1, the second counter circuit 2 and the counter output switching circuit 3 are in, is cleared.

FIG. 2 is a diagram showing the configuration of the HA macro 4 used in the counter circuit shown in FIG. 1C.

The HA macro shown in FIG. 2 comprises an inverter 10 and a D flip-flop 11 where the input signals to the input terminal CI are provided to D flip-flop 11 through the inverter 10. The D flip-flop 11 is a commonly used D flip-flop.

The signal with a period twice as short as the input signal is output from the output terminal DA and the inverted signal of the output signal from the output terminal DA (the signal with phase difference π [rad]) is output from the output terminal DX.

As a result of the reset signal from the input terminal CL, the state of the D flip-flop is cleared. In other words, when the reset signal is low, the state of D flip-flop is cleared.

FIG. 3 is a diagram showing the configuration of the FA macros 5a through 5n used in the counter circuit shown in FIG. 1C.

The FA macro shown in FIG. 3 comprises an inverter 12 and a D flip-flop 13, and the input signal to the input terminal CI is provided to D flip-flop 13 through inverter 12. The D flip-flop 13 shown in FIG. 3 is also a commonly used flip-flop.

Therefore, a signal with a period twice as short as the input signal is output from the output terminal DA and the state of D flip-flop is cleared when the reset signal is applied from the input terminal CL.

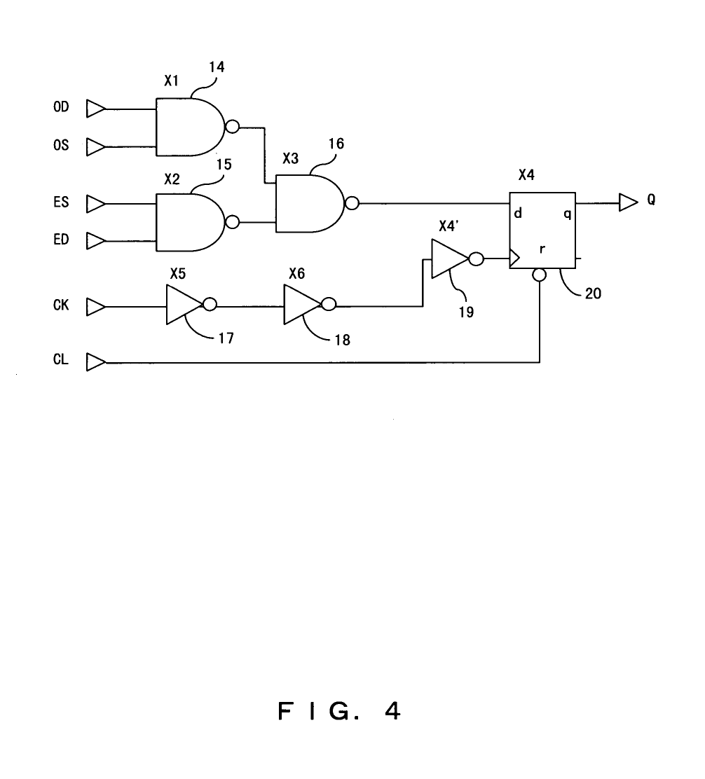

FIG. 4 is a diagram showing the configuration of one of the SW macros 6a through 6h used in the counter circuit shown in FIG. 1C.

The SW macro shown in FIG. 4 is a circuit comprising NAND gates 14 through 16, inverters 17 though 19, and a D flip-flop 20. The output signal of the first counter circuit 1 is input to terminal OD of NAND gate 14, and the first counter select signal from the output selection circuit 9 is applied to input terminal OS. The output signal of the second counter circuit 2 is input to terminal ED of NAND gate 15 are input to the input terminal ED, and the second counter select signal from the output selection circuit 9 are applied to the input terminal ES.

Accordingly, NAND gates 14 through 16 switch the output signal of the first counter circuit 1 and the second counter circuit 2 in response to the first counter select signal and the second counter select signal, and the output signals are applied to D flip-flop 20. For example, when the first counter select signal of the output selection circuit 9 is high, and the output signal of the first counter circuit 1 is also high, a high signal are input to an input terminal d of the D flip-flop 20. When the second counter select signal of the output selection circuit 9 is high and the output signal of the second counter circuit 2 is also high, a high-level signal is input to an input terminal d of the D flip-flop 20.

The inverters 17 and 18 are inserted to adjust the time lag caused by the NAND circuits 14 through 16.

The above operations allow the SW macros to select the output signal from the first counter circuit 1 input to the input terminal OD, and to latch and output the signal in accordance with the clock signal input to the input terminal CK, when the first counter select signal from the output selection circuit 9 input to the input terminal OS is high. The above operations also allow the SW macros to select the output signal from the second counter circuit 2 input to the input terminal ED, and to latch and output the signal in accordance with the clock signal input to the input terminal CK when the second counter select signal from the output selection circuit 9 input to the input terminal ES is high.

In the explanation above, the first counter circuit 1, the second counter circuit 2 and the counter output switching circuit 3, relating to the present invention, all comprise D flip-flops, however it is not limited to this configuration. In other words, circuits comprising a similar function to the D flip-flop shown in the present invention by the combination of logic circuits and RS flip-flops or JK flip-flops, for example. Circuits comprising the combination of logic circuits with a similar function to a D flip-flop can also be used.

The counter circuit relating to the present invention is an example of an 8-bit counter circuit, however it is not limited to 8-bits. That is, the present invention can be applied to counter circuits counting by an arbitrary number of bits.

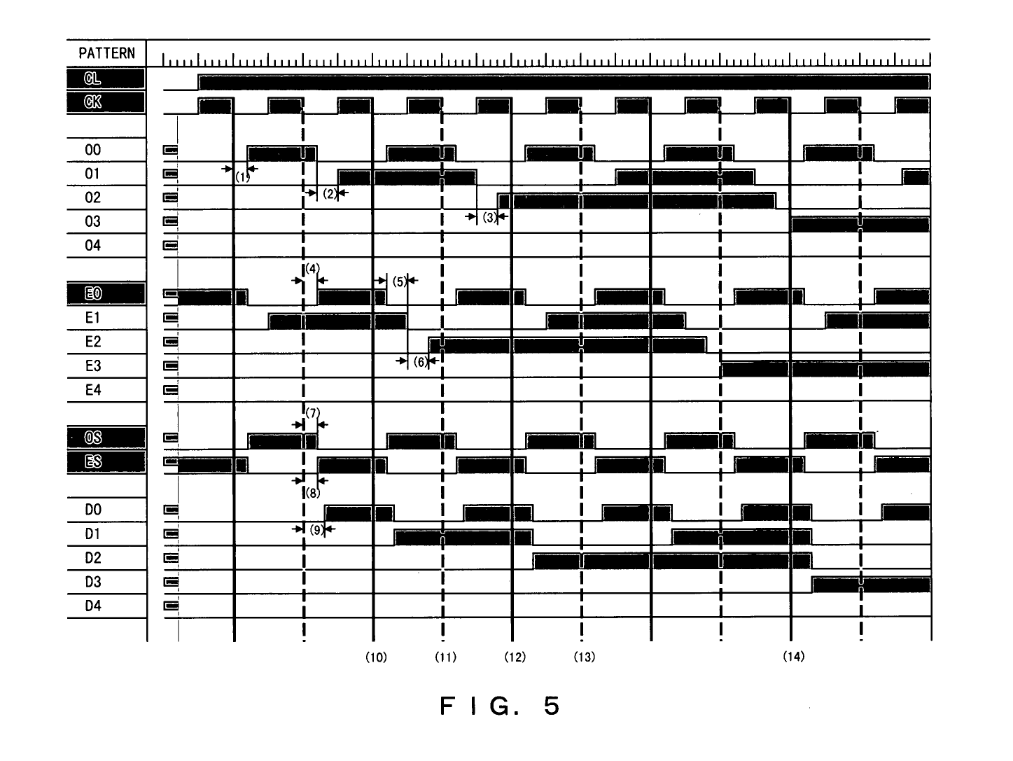

FIG. 5 is a timing chart showing some of the more important signals in the counter circuit relating to the present invention.

FIG. 5 is a timing chart showing the relation of the clear signal to the input terminal CL and the clock signal to the input terminal CK of the counter circuit shown in FIG. 1C, the output signal of the output terminal O0 of the HA macro 4 and the output terminals O1 through O4 of the FA macros 5a through 5d in the first counter circuit 1, the output signal of the output terminal E0 and the output terminal E1 through E4 of the FA macros 5h through 5k in the second counter circuit 2, the first and the second counter select signal of the output terminals OS and ES of the output selection circuit 9 in the counter output switching circuit 3, and the output signal of the output terminals D0 through D4 corresponding to the SW macros 6a through 6e in the counter output selection circuit 3 (the output signal of the counter circuit relating to the present invention).

In the explanation below, labels of the output terminals shown in FIG. 5 represent the output signal of the output terminals. For example, “signal CK” represents the output signal from the output terminal CK.

The signal O0 is the output signal of the HA macro 4 in the first counter circuit 1. Thus, at the time that the signal CK becomes low, the signal O0 is switched from high to low or from low to high, and the period of the signal period becomes twice that of the signal CK.

At times when the signal CK is low, the output signal of the HA macro 4 (the signal from the output terminal DA) is switched, however the switching of the signal is not instantaneous and causes carry time lag (the time period (1) in FIG. 5, for example).

The signal O1 is the output signal of the FA macro 5a in the first counter circuit 1. Therefore, at times when the signal O0 is low, the signal O1 is switched from high to low or from low to high, and the period of the signal becomes twice that of the signal O0.

At times when the signal O0 is low, the output signal of the FA macro 5a is switched, however the switching of the signals is not instantaneous and causes carry time lag (the time period (2) in FIG. 5, for example).

Similarly, the signal O2 is the output signal of the FA macro 5b in the first counter circuit 1. At times when the signal O1 is low, the signal O2 is switched from high to low or from low to high, and the period of the signal becomes twice that of the signal O1.

At times when the signal O1 is low, the output signal of the FA macro 5b is switched, however the switching of the signal is not instantaneous and causes carry time lag (the time period (3) in FIG. 5, for example).

By similar operations to those explained above, the signals O3 through O7 in the first counter circuit 1 shown in FIG. 1C are output.

The signal E0 is the output signal from the output terminal DX of the HA macro 4 in the first counter circuit 1, and has a phase difference of π [rad] compared with the signal O0. Therefore, at the time that the signal CK becomes low, the signal E0 is switched from high to low or low to high, maintaining a phase difference of π [rad] from the signal O0. The period of the signal is twice that of the signal CK.

At times when the signal CK is low, the output signal of the HA macro 4 (the signal from the output terminal DX) is switched, however the switching of the signal is not instantaneous and causes carry time lag (the time period (4) in FIG. 5, for example).

The signal E1 is the output signal of the FA macro 5h in the second counter circuit 2. Therefore, at the time that the signal E0 becomes low, the signal E1 is switched from high to low or from low to high, and the period of the signal becomes twice that of the signal E0.

At times when the signal E1 is low, the output signal of the FA macro 5h is switched, however the switching of the signal is not instantaneous and causes carry time lag (the time period (5) in FIG. 5, for example).

Similarly, the signal E2 is the output signal of the FA macro 5i in the second counter circuit 2. At times when the signal E1 is low, the signal E2 is switched from high to low or from low to high, and the period of the signal becomes twice that of the signal E1.

At times when the signal E1 is low, the output signal of the FA macro 5i is switched, however the switching of the signal is not instantaneous and causes carry time lag (the time period (6) in FIG. 5, for example).

By similar operations to those explained above, the signals E3 through E7 in the second counter circuit 2 shown in FIG. 1C are output.

The signal OS is the output signal of the output selection circuit 9 in the counter output switching circuit 3 (the output signal from the output terminal q of the D flip-flop 8). Therefore, at times when the signal CK becomes low, the signal OS is switched from high to low or from low to high. The period of the signal becomes twice that of the signal CK.

Similarly, the signal ES is the output signal of the output selection circuit 9 in the counter output switching circuit 3 (the output signal from the output terminal d of the D flip-flop 8). Thus, the signal has a phase difference of π [rad] from the signal OS, and the period of the signal is twice that of the signal CK.

At times when the signal CK becomes low, the output signal of the D flip-flop 8 (the output signal from the output terminal d and q) is switched, however the switching of the signals is not instantaneous and causes carry time lag (the time periods (7) and (8) in FIG. 5, for example) for the signal OS and the signal ES.

The signal D0 is the output signal of the SW macro 6a when the input to terminals OD and ED is the signal O0. At times when the signal CK is low, the signal D0 is switched from high to low or from low to high, thus D0 is a signal with a phase difference of π [rad] compared with the signal O0. At times when the signal CK is low, the output signal of the SW macro 6a (the signal from the output terminal Q) is switched, however the switching of the signals is not instantaneous and causes carry time lag (the time period (9) in FIG. 5, for example).

The signal D1 is the output signal selected from either the signal O1 or the signal E1 by the SW macro 6b depending on the state of the first counter select signal OS and the second counter select signal ES. For example, at times (10) (the times when the signal CK is low indicated in solid lines in FIG. 5), the signal ES sent to the SW macro 6b is high and the signal E1 is also high, therefore the signal D1 of the SW macro 6b switches from low to high.

At times (11) (the time when the signal CK is low indicated by broken lines in FIG. 5), the signal OS sent to the SW macro 6b is high and the signal O1 is also high, therefore the signal D1 of the SW macro 6b remains high.

At time (12) (the time when the signal CK is low indicated by solid lines in FIG. 5), the signal ES sent to the SW macro 6b is high and the signal E1 is low, therefore the signal D1 of the SW macro 6b switches from high to low.

Here, regarding the above timing (10) and (12), the signal D1 switches from low to high or from high to low at times that the signal CK is low. This switch also causes carry time lag.

However, the SW macro 6b switches the signal at times that the signal CK is low, based on the first counter select signal OS and the second counter select signal ES. The carry time lag of the signal D0 from the signal CK and the carry time lag of the signal D1 from the signal CK are nearly equal. Thus the carry time lag of the signal D1 from the signal D0 can be disregarded. That is, at times when the signal D0 is low, the signal D1 can be switched from high to low or from low to high without the carry time lag.

In a similar way, the signal D2 is the output signal selected from either the signal O2 or the signal E2 by the SW macro 6c depending on the state of the first counter select signal OS and the second counter select signal ES. For example, at the time (12) (the time when the signal CK is low indicated by a solid line in FIG. 5), the signal ES sent to the SW macro 6c is high and the signal E2 is also high, therefore the signal D2 of the SW macro 6c switches from low to high.

At the time (13)(the time when the signal CK is low indicated by a broken line in FIG. 5), the signal OS sent to the SW macro 6c is high and the signal O2 is also high, therefore the signal D1 of the SW macro 6c remains high.

At the time (14)(the time when the signal CK is low indicated by a solid line in FIG. 5), the signal ES sent to the SW macro 6c is high and the signal E2 is low, therefore the signal D2 of the SW macro 6c switches from high to low.

Here, regarding the above timing (12) and (14), the signal D2, similarly to the signal D1, switches from low to high or from high to low at the timing when the signal CK becomes low. This switch also causes carry time lag.

However, the SW macro 6c switches the signal D2 at the timing that the signal CK becomes low, based on the first counter select signal OS and the second counter select signal ES. The carry time lag of the signal D1 from the signal CK and the carry time lag of the signal D2 from the signal CK are nearly equal. Thus the carry time lag of the signal D2 from the signal D0 and D1 can be disregarded. That is, at the timing when the signal D1 becomes low, the signal D2 can be switched from high to low or from low to high without carry time lag.

By similar operations to those explained above, the signals D3 through D7 are output in the counter output switching circuit 3 shown in FIG. 1C.

On using the counter circuit explained above, the carry time lag from the HA macro 4 to the FA macro 5g in the first counter circuit 1 or the carry time lag from the HA macro 4 in the first counter circuit 1 and the FA macros 5h to 5n in the second counter circuit 2 should be within a period of the signal CK signal.

Then, the period of the clock signal, which is an external input signal (input signal to the input terminal CK of FIG. 1C), can be made faster up to the period T calculated by the equation (1).
T=T0+π/N (1)

Where T0 is the shortest period at which the LSB of the first counter circuit 1 can be operated and T is the carry time lag of all bits (for example, the carry time lag of the HA macro 4, or LSB, and FA macros 5a through 5g or the carry time lag of the FA macros 5h through 5n shown in FIG. 1C), N is the number of counters (in FIG. 1C, N is 2 because two counter circuits, the first counter circuit 1 and the second counter circuit 2 are used).

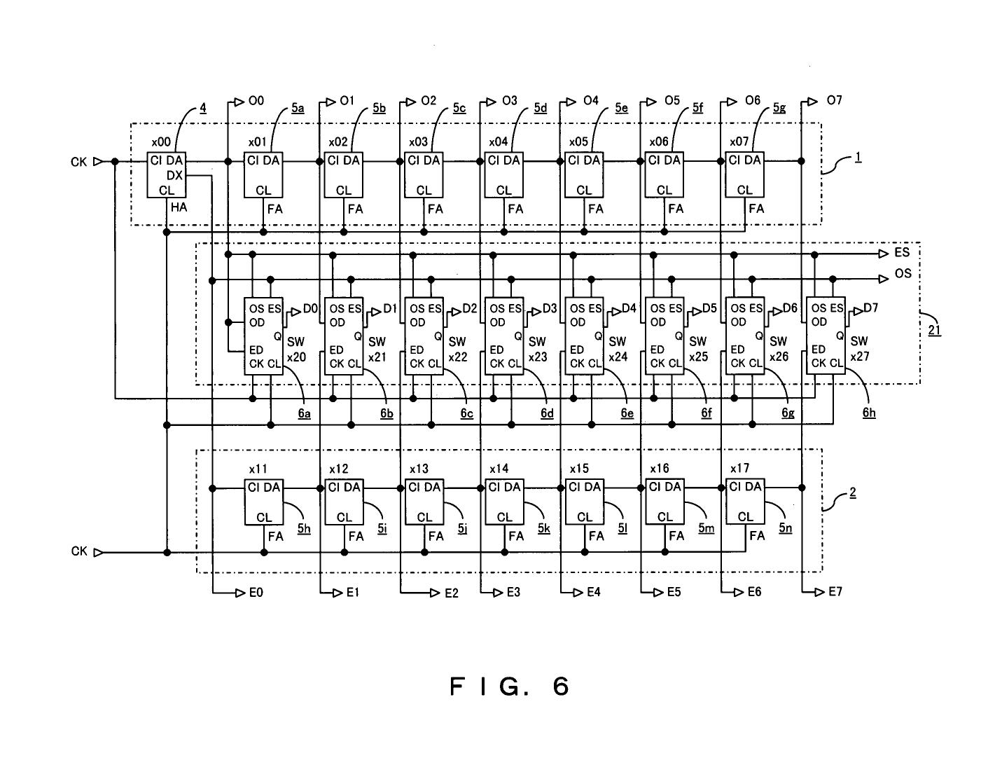

FIG. 6 is a diagram showing a variation in configuration of the counter circuit relating to the present invention.

The counter circuit shown in FIG. 6 is an example of a configuration in which the HA macro 4 in the first counter circuit 1 serves the function of the output selection circuit 9 in the counter circuit shown in FIG. 1C. It is the counter circuit comprising a first counter circuit 1, which counts the clock signal input from the input terminal CK, a second counter circuit 2, which counts the clock signal also input from the input terminal CK, a counter output switching circuit 21, which switches the output signal of the first counter circuit 1 and that of the second counter circuit 2.

The first counter select signal OS and the second counter select signal ES in the counter output switching circuit 21 shown in FIG. 6 are the output signal of the output terminal DA and that of the output terminal DX, respectively, of the HA macro 4 in the first counter circuit 1.

The first counter select signal OS in FIG. 6 is the output signal from the output terminal DA of the HA macro 4 shown in FIG. 1C, that is the output signal of the output terminal O0, and the second counter select signal ES in FIG. 6 is the output signal from the output terminal DX of the HA macro 4 shown in FIG. 1C, that is the output signal of the output terminal E0.

According to FIG. 5, it is indicated that the signal O0 and the signal OS are identical and the signal E0 and the signal ES are also identical. For that reason, the explanation of the configuration and operation is omitted because the counter circuit comprises the same configuration and the same operation as the counter circuit shown in FIG. 1C except that the first counter select signal OS and the second counter select signal ES are generated by the HA macro 4.

By the configuration explained above, the output selection circuit 9 shown in FIG. 1C can be combined into the HA macro 4, therefore the counter circuit can be downsized compared with the counter circuits shown in FIG. 1C.

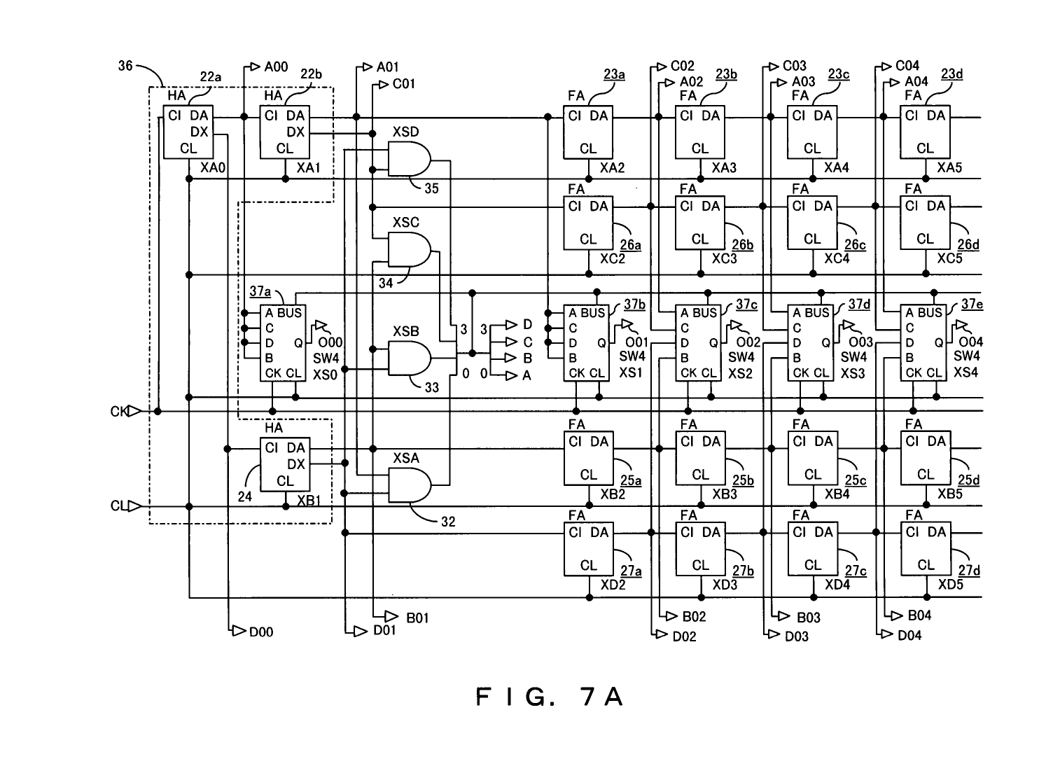

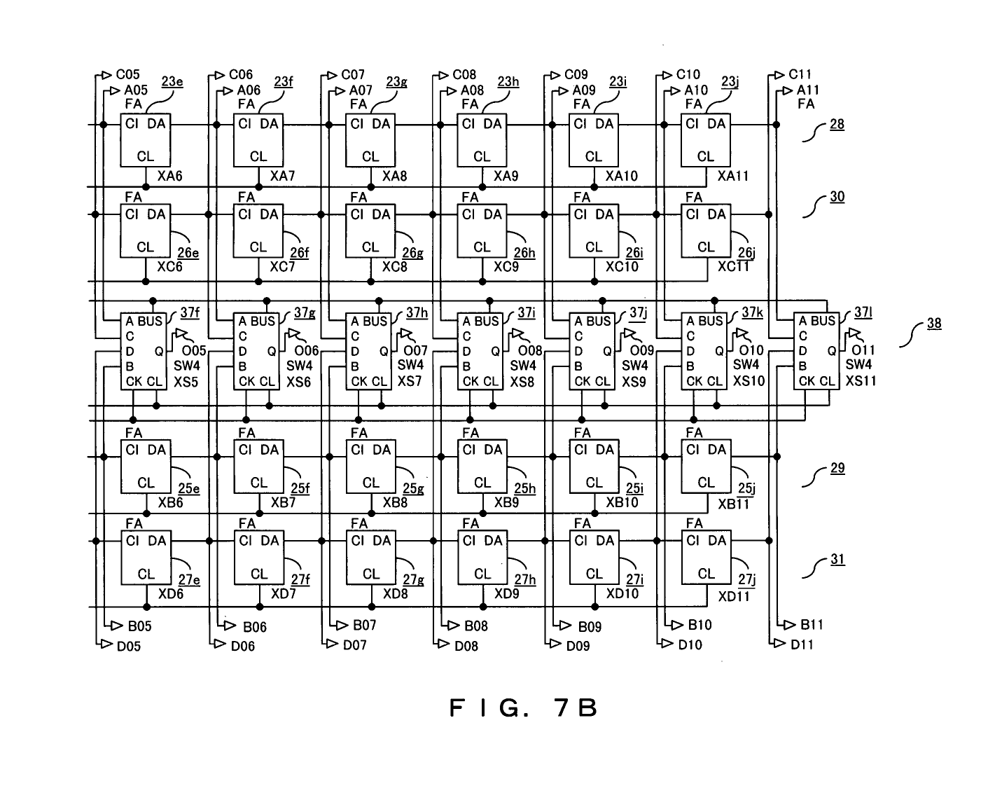

FIG. 7A and FIG. 7B are diagrams showing a variation in configuration of the counter circuit relating to the first embodiment.

The counter circuits shown in FIG. 7A and FIG. 7B are examples of a configuration where the number of steps of the counter circuit is four (the first counter circuit 28, the second counter circuit 29, the third counter circuit 30 and the fourth counter circuit 31) and the number of steps in the counter shown in FIG. 1C is two (the first counter circuit 1 and the second counter circuit 2). The counter circuit comprises a first counter circuit 28, a second counter circuit 29, a third counter circuit 30, a fourth counter circuit 31, which count the clock signal input from the input terminal CK, and a counter output switching circuit 38, which switches the output signal of the first counter circuit 28, that of the second counter circuit 29, that of the third counter circuit 30, and that of the fourth counter circuit 31.

A phase control circuit 36 comprises the function of the output selection circuit 9 shown in FIG. 1C. Therefore the output signal of the phase control circuit 36, the signal A01, the signal B01, the signal C01 and the signal D01, are first counter select signal, second counter select signal, third counter select signal and fourth counter select signal, respectively.

The first counter circuit 28 comprises HA macros 22a and 22b shown in FIG. 2, and FA macros 23a through 23j shown in FIG. 3.

The clock signal with period T[s] input from the input terminal CK is provided to the input terminal CI of the HA macro 22a, and the clock signal with period 2T[s] is output from the output terminal DA. The output from the HA macro 22a is provided to the input terminal CI of the HA macro 22b, and the clock signal with period 4T[s] is output from the output terminal DA. The output is provided to the input terminal CI of the FA macro 23a. Similarly, the FA macros, receiving input of the signal output from any one FA macro, output a signal with a period twice that of the input signal.

In such a case, the output signal of the HA macro 22a (the output signal from the output terminal A00) is the LSB, and the output signal of the FA macro 23j (the output signal of the output terminal A11) is the MSB.

The second counter circuit 29 comprises the HA macro 24 shown in FIG. 2 and the FA macros 25a through 25j shown in FIG. 3.

The clock signal with period T[s] input from the input terminal CK is provided to the input terminal CI of the HA macro 22a, and the clock signal with period 2T[s] and a phase difference of π [rad] is output from the output terminal DX. The output from the HA macro 22a is provided to the input terminal CI of the HA macro 24, the clock signal with period 4T[s]is output from the output terminal DA, and the clock signal is input to the input terminal CI of the FA macro 25a. Similarly, the FA macros, receiving input of the signal output from any one FA macro, output a signal with a period twice that of the input signal.

In such a case, the output signal of the HA macro 22a (the output signal from the output terminal A00) is the LSB, and the output signal of the FA macro 25j (the output signal of the output terminal B11) is the MSB.

The third counter circuit 30 comprises the FA macros 26a through 26j shown in FIG. 3. The clock signal with period T[s] input from the input terminal CK is provided to the input terminal CI of the HA macro 22a, and the clock signal with period 2T[s] is output from the output terminal DA. The output from the HA macro 22a is provided to the input terminal CI of the HA macro 22b, and the clock signal with period 4T[s]and a phase difference of π [rad] is output from the output terminal DX. The output is provided to the input terminal CI of the FA macro 26a. Similarly, the FA macros, receiving input of the signal output from any one FA macro, output a signal with a period twice that of the input signal.

In this case, the output signal of the HA macro 22a (the output signal from the output terminal A00) is the LSB, and the output signal of the FA macro 26j (the output signal of the output terminal C11) is the MSB.

The fourth counter circuit 31 comprises the FA macros 27a through 27j shown in FIG. 3.

The clock signal with a period T[s] input from the input terminal CK is provided to the input terminal CI of the HA macro 22a, and the clock signal with period 2T[s] and a phase difference of π [rad] is output from the output terminal DX. The output from the HA macro 22a is provided to the input terminal CI of the HA macro 24, the clock signal with a period 4T[s] and a phase difference of π [rad] is output from the output terminal DX, and the clock signal is input to the input terminal CI of the FA macro 27a. Similarly, the FA macros, receiving input of the signal output from any one FA macro, output a signal with a period twice that of the input signal.

In such a case, the output signal of the HA macro 22a (the output signal from the output terminal A00) is the LSB, and the output signal of the FA macro 27j (the output signal of the output terminal B11) is the MSB.

The counter output switching circuit 38 comprises the phase control circuit 36, comprising the HA macros 22a and 22b and the HA macro 24, AND gates 32 through 35, and the SW macros 37a through 37l.

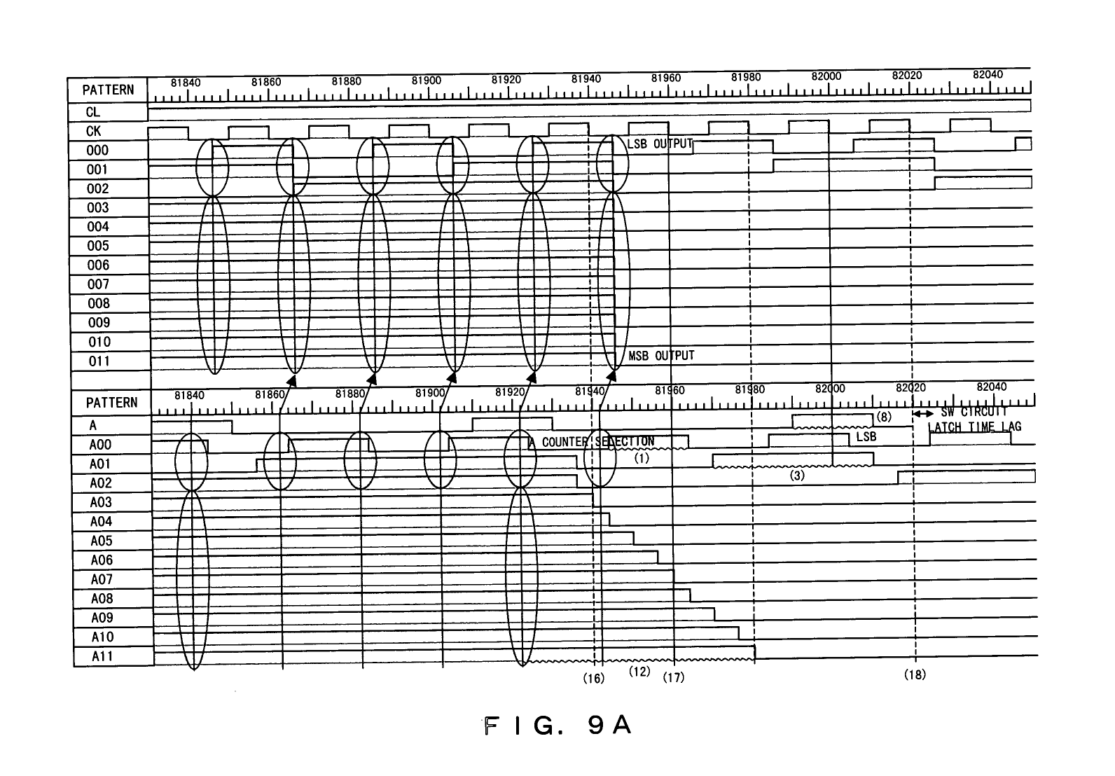

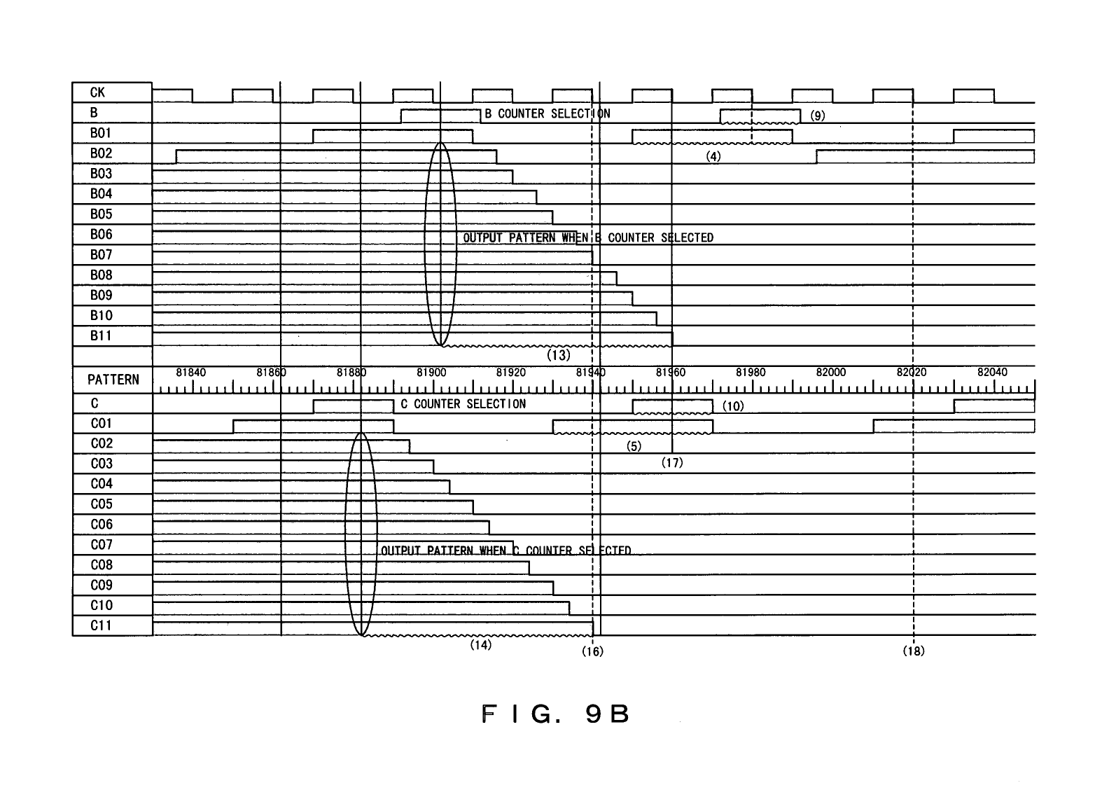

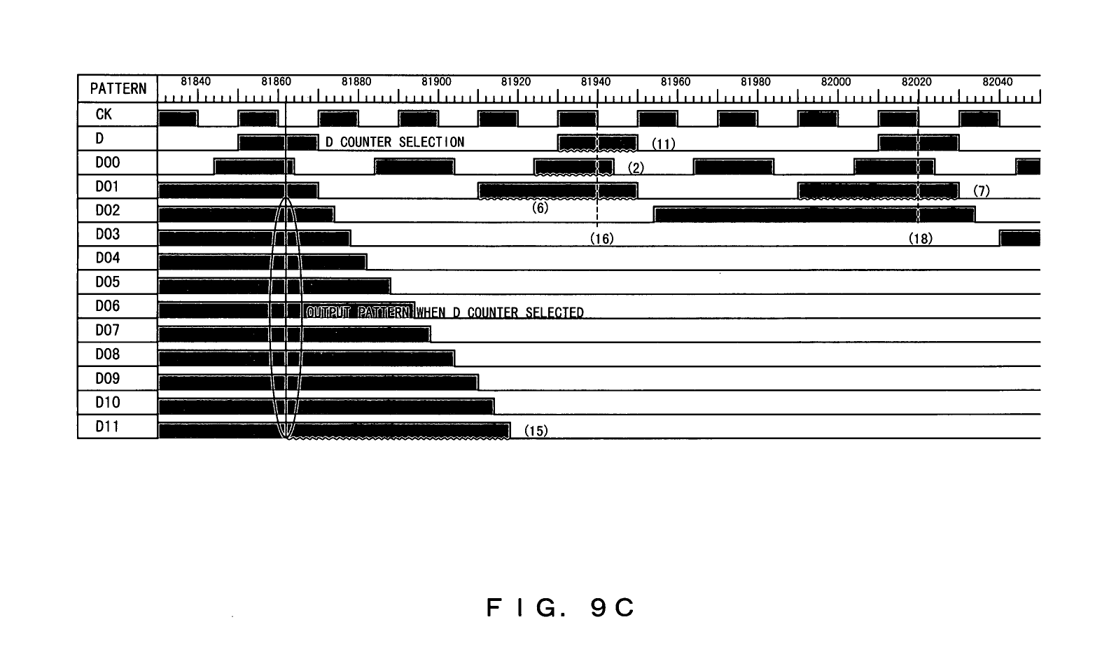

In phase control circuit 36, as stated above, the signal D00 (the wavy line (2) in FIG. 9C, for example) is a signal with phase difference of π [rad] from the signal A00 (the wavy line (1) in FIG. 9A, for example), the signal C01 (the wavy line (5) in FIG. 9B, for example) is the signal with a phase difference of π [rad] from the signal A01 (the wavy line (3) in FIG. 9A, for example), and the signal D01 (the wavy line (6) in FIG. 9C, for example) is the signal with phase difference of π [rad] from the signal B01 (the wavy line (4) in FIG. 9B, for example).

The signal B01, the signal C01, and the signal D01 have phase differences of 0.5π [rad], 1.0π [rad]and 1.5π [rad], respectively, from the signal A01.

In AND circuits 32 through 35, the first counter select signal (wavy line (8) in FIG. 9A, for example), the second counter select signal (wavy line (9) in FIG. 9B, for example), the third counter select signal (wavy line (10) in FIG. 9B, for example) and the fourth counter select signal (wavy line (11) in FIG. 9C, for example) are generated by the AND operation of signals D01 and the signal A01 (wavy line (7) in FIG. 9C and wavy line (3) in FIG. 9A, for example), the signal A01 and the signal B01 (wavy line (3) in FIG. 9A and wavy line (4) in FIG. 9B, for example), the signal B01 and the signal C01 (wavy line (4) and wavy line (5) in FIG. 9B, for example) and the signal C01 and the signal D01 (wavy line (5) in FIG. 9B and wavy line (6) in FIG. 9C, for example), respectively.

The SW macros 37a through 37k switch the output signal of the first counter circuit 28 through the fourth counter circuit 31 and output to the output terminal O00 through O11, in response to the first counter select signal, the second counter select signal, the third counter select signal and the fourth counter select signal, respectively.

The present invention is configured in such a way that the HA macro 22a (LSB in the counter circuit) in the first counter circuit 28 is shared by the LSB of the second counter circuit 29, the third counter circuit 30, and the fourth counter circuit 31, and the HA macro 22b in the first counter circuit 28 and the HA macro 24 in the second counter circuit 29 are shared by the third counter circuit 30 and the fourth counter circuit 31 for the purpose of parts sharing (i.e. circuit size-reduction). However, the present invention is not limited to this configuration.

That is, the first counter circuit 28, the second counter circuit 29 the third counter circuit 30 and the fourth counter circuit 31 can comprise separate macros from LSB to MSB with dedicated HA macros and FA macros. In such a case, additional circuits, a phase control circuit for controlling phases of the counter circuits and a counter output switching circuit for selecting the output signal of the first counter circuit 28 through the fourth counter circuit 31, should be comprised.

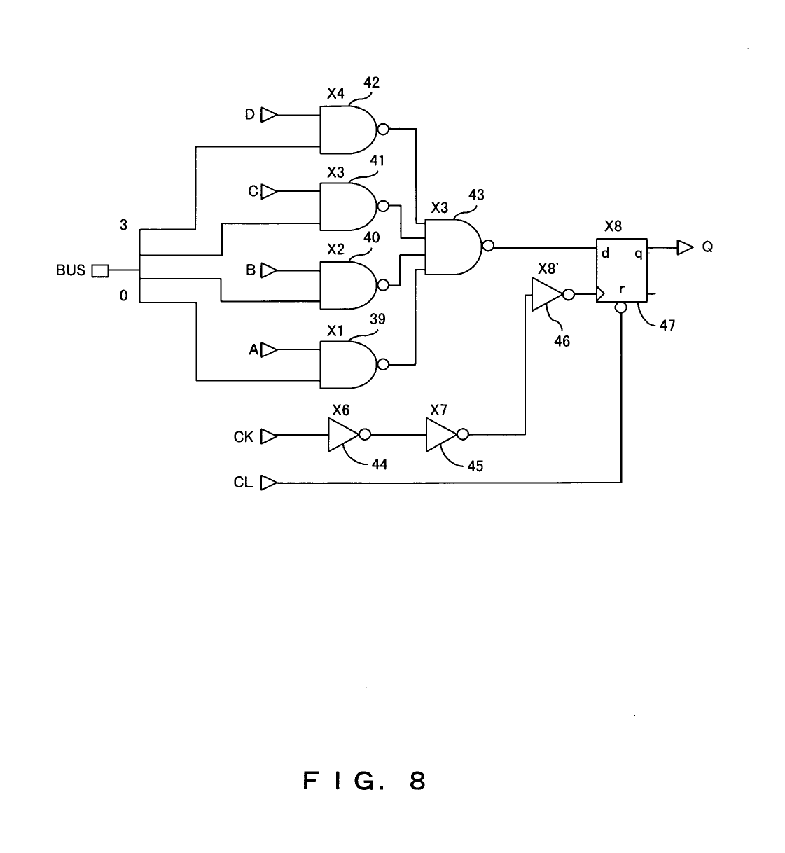

FIG. 8 is a diagram describing the configuration of the SW macros 37a through 37l used in the counter circuit shown in FIG. 7A and FIG. 7B.

The SW macro shown in FIG. 8 is a circuit comprising NAND gates 39 through 43, inverters 44 through 46 and a D flip-flop 47.

The NAND gate 39 receives the output signal of the first counter circuit 28 and the first counter select signal A01 as input, the NAND gate 40 receives the output signal of the second counter circuit 29 and the second counter select signal B01 as an input, the NAND circuit 41 receives the output signal of the third counter circuit 30 and the third counter select signal C01 as input, and the NAND gate 42 receives the output signal of the fourth counter circuit 31 and the fourth counter select signal D01 as input.

NAND gates 39 through 43 switch the output signal of the first counter circuit 28, the second counter circuit 29, the third counter circuit 30 and the fourth counter circuit 31 in response to the first counter select signal, the second counter select signal, the third counter select signal and the fourth counter select signal, and output to the D flip-flop 47.

For example, when the first counter select signal is high and the output of the first counter circuit 28 is also high, a high-level signal is input to the input terminal d of the D flip-flop 47. When the second count select signal is high and the output of the second counter circuit 29 is high, a high-level signal is input to the input terminal d of the D flip-flop 47.

Similarly, when the third count select signal is high and the output of the third counter circuit 30 is high, a high-level signal is input to the input terminal d of the D flip-flop 47. When the fourth count select signal is high and the output of the fourth counter circuit 31 is high, a high-level signal is input to the input terminal d of the D flip-flop 47.

The inverters 44 through 46 are inserted in order to adjust the time lag caused by the NAND circuits 39 through 43.

The above operation allows the SW macros to select the output signal from the first counter circuit 28 and to latch and output the signal in accordance with the clock signal input to the input terminal CK when the first counter select signal is high, and to select the output signal from the second counter circuit 29 and to latch and output the signals in accordance with the clock signal input to the input terminal CK when the second counter select signal is high.

In a similar way, the SW macros select the output signal from the third counter circuit 30 and latch and output the signals in accordance with the clock signal input to the input terminal CK when the third counter select signal is high, and select the output signal from the fourth counter circuit 31 and latch and output the signals in accordance with the clock signal input to the input terminal CK when the fourth counter select signal is high.

FIG. 9A through FIG. 9C are timing charts of some of the more important signals in the example of a variation of the counter circuit relating to the first embodiment shown in FIG. 7A and FIG. 7B.

FIG. 9A through FIG. 9C show the relation of the clear signal to the input terminal CL of the counter circuit and the clock signal to the input terminal CK shown in FIG. 7A and FIG. 7B, the output signals O00 through O11 of the counter circuits, the first counter select signal A and the signals A00 through A11 in the first counter circuit 28, the second counter select signal B and the signals B00 through B11 in the second counter circuit 29, the third counter select signal C and the signals C00 through C11 in the third counter circuit 30, and the fourth counter select signal D and the signals D00 through D11 in the fourth counter circuit 31.

The signal A00 is an output signal of the HA macro 22a in the first counter circuit 28. At the timing when the signal CK becomes low, the signal A00 switches from high to low or from low to high. The signal period becomes twice that of the signal CK.

At the timing when the signal CK becomes low, the signal A00 is switched, however the switching of the signal is not instantaneous and causes carry time lag (A00 in the time period with wavy line (1) in FIG. 9A, for example).

The carry time lag of the signals A01 through A11 is generated by similar operations (A01 through A11 in the time period with a wavy line (12) in FIG. 9A, for example).

In a similar way, a carry time lag of the signals B01 through B11, the signals C01 through C11, and the signals D01 through D11 are generated in the second counter circuit 29, in the third counter circuit 30 and in the fourth counter circuit 31, respectively (B01 through B11, C01 through C11 and D01 through D11 in the time period with wavy lines (13) and (14) in FIG. 9B and with wavy line (15) in FIG. 9C, for example).

The signal A00 is always used for the output signal O00 of the counter circuit, and the signal A01 in the output signal from the phase control circuit 36 is always used for the signal O01.

In response to the first counter select signal through the fourth counter select signal, the output signals O02 through O11 from the counter circuit switch the output signals from the first counter circuit 28, the second counter circuit 29, the third counter circuit 30 and the fourth counter circuit 31, and are output.

For example, regarding signal A02, at the timing (16) in FIGS. 9A, 9B and 9C, the fourth counter select signal is high, and the signal D02 is low. Thus, the output signal O02 of the counter circuit is switched from high to low.

At the time (17), the third counter select signal is high and the signal C02 is low, the output signal O02 of the counter circuit remains low.

At the timing (18), the fourth counter select signal is high and the signal D02 is also high, the output signal O02 of the counter circuit is switched from low to high.

The SW macros 37c through 37l switch the signals at the timing when the signal CK becomes low based on the first counter select signal through the fourth counter select signal. Therefore, the carry time lag of the output signals O02 through O11 is the time lag of the switching of the signal CK.

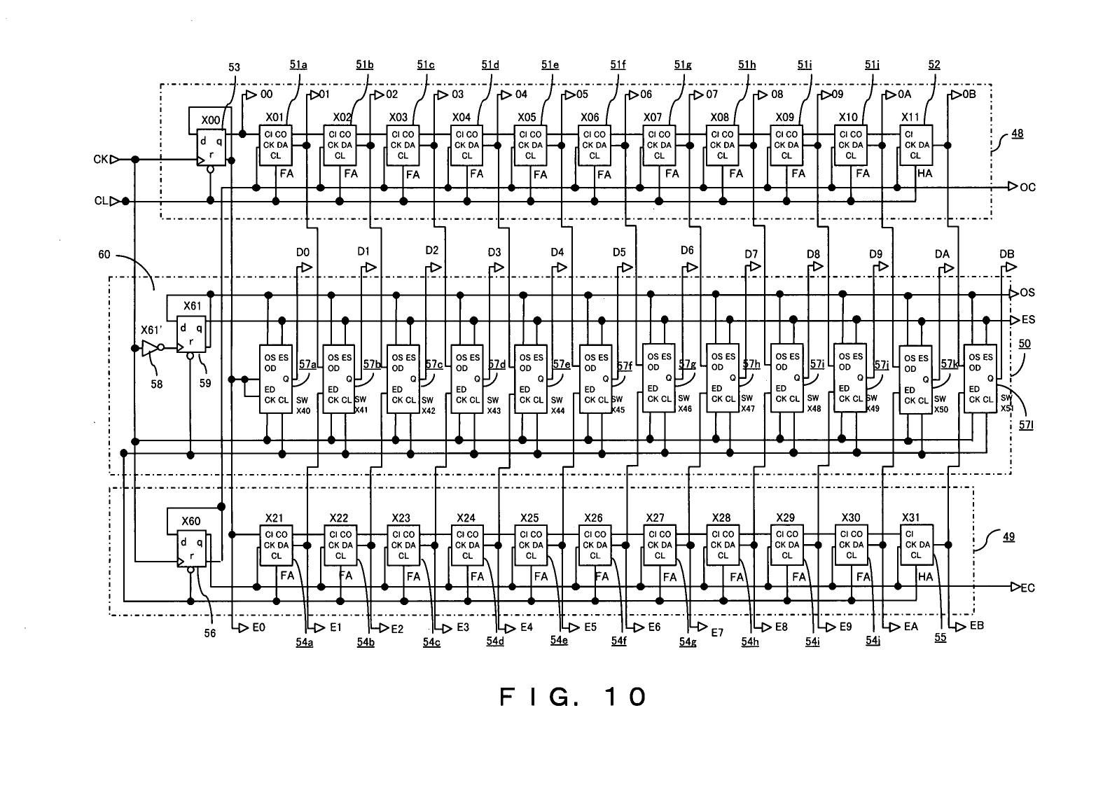

An explanation of the second embodiment relating to the present invention is provided below based on FIG. 10 through FIG. 15.

FIG. 10 describes an example of the configuration of the second embodiment relating to the present invention.

The counter circuit shown in FIG. 10 is a synchronous counter circuit comprising first counter circuit 48, which counts the input clock signal from the input terminal CK, second counter circuit 49, which counts the input clock signal from the input terminal CK, a counter output switching circuit 50, which switches the output signal of the first counter circuit 48 and the output signal of the second counter circuit 49.

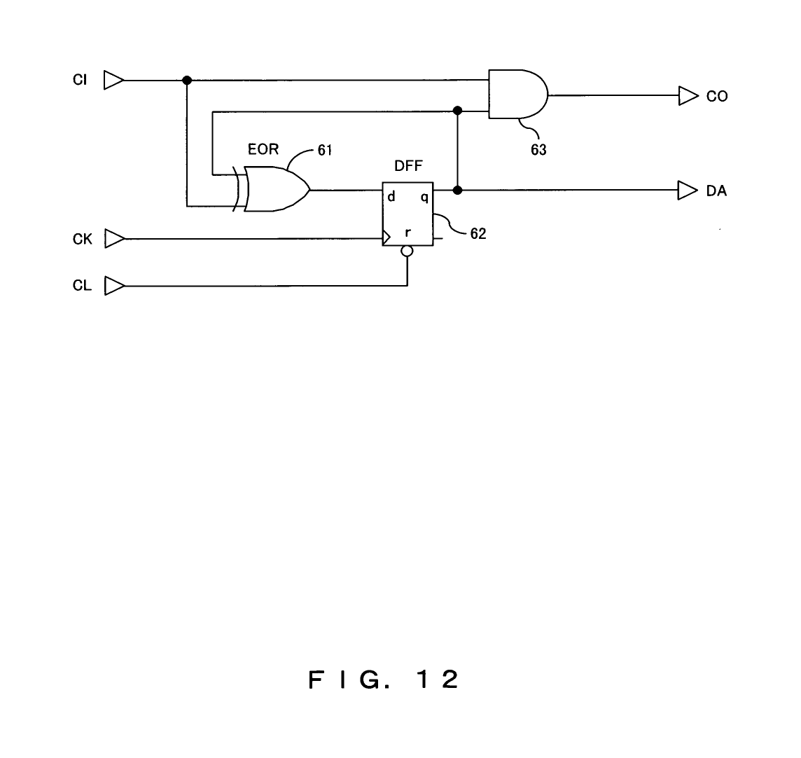

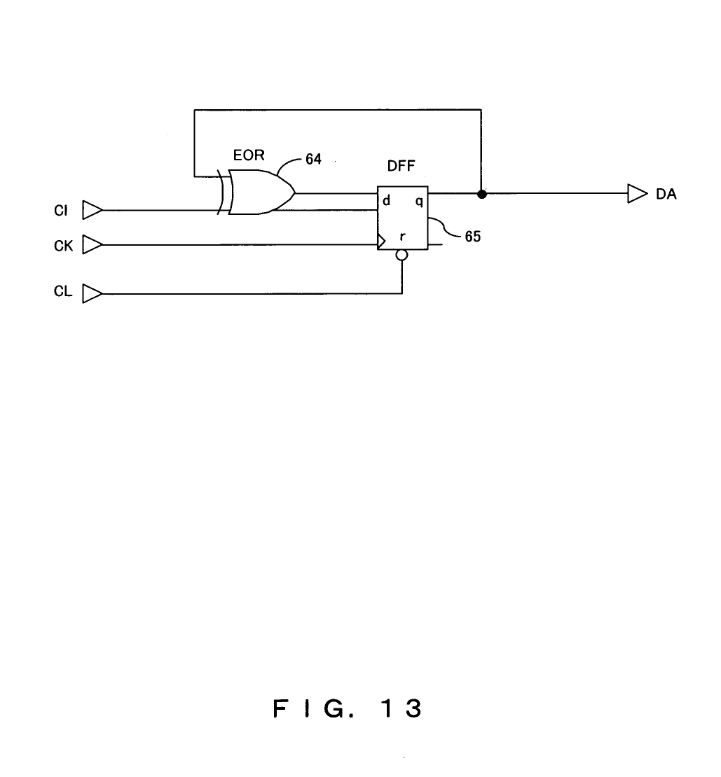

The first counter circuit 48 comprises the FA macros 51a through 51j shown in FIG. 12, the HA macros 52 shown in FIG. 13, and the D flip-flop 53.

The clock signal with a period T[s] input from the input terminal CK is provided to the D flip-flop 53, and the clock signal with a period 2T[s] is output from the output terminal q. The clock signal from the input terminal CK is provided to the D flip-flop 56 and divided into two (this demultiplied signal is hereafter referred to as the demultiplied clock signal). The FA macros 51a through 51j and the HA macro 52 are synchronized with the demultiplied clock signal, and are count processed. Similarly the FA macro 54a through 54j and the HA macro 55 is synchronized with the inverted signal of the demultiplied clock signal (a signal with a leading phase difference of π), and are count processed.

The output signal of the D flip-flop 53 is applied to the input terminal CI of the FA macro 51a, and is synchronized with the demultiplied clock signal. The clock signal with a period 4T[s] is output from the output terminal CO and input to the input terminal CI of the FA macro 51b. In a similar way, the FA macros 51, which receive input of the output signal from any one FA macro 51, output the signal with a period twice that of the input signal. At the completion, the output signal of the FA macro 51j is provided to the input terminal CI of the HA macro 52, and is output from the output terminal DA.

In this case, the output signal of the D flip-flop 53 (the output signal from the output terminal O0) is the LSB, and the output signal of the HA macro 52 (the output signal of the output terminal OB) is the MSB.

Because the first counter circuit 48 is a synchronous counter circuit, the D flip-flop 53 is synchronized with the clock signal CK, also the FA macros 51a through 51j and the HA macro 52 are synchronized with the demultiplied clock signal, and then the output signals O0 through OB are output.

The second counter circuit 49 comprises the FA macros 54a through 54j shown in FIG. 12 and the HA macro 55 shown in FIG. 13 and a D flip-flop 56.

The clock signal with period T[s] is input to the D flip-flop 53 from the input terminal CK, and a signal with a period 2T[s] and a phase difference (the leading phase difference) of π [rad]from the output signal from the output terminal q (the demultiplied clock signal) is input to the input terminal CI of the FA macro 54a. The FA macro 54a is synchronized with the demultiplied leading phase clock signal, and outputs the clock signal with a period of 4T[s] from the output terminal CO, and provides it to the input terminal CI of the FA macro 54b. Similarly, the other FA macros 54, which receive input of the output signal of any one FA macro 54, output a signal with a period twice that of the input signal. Upon completion of proicessing, the output signal of the FA macro 54j is provided to the input terminal CI of the HA macro 55, and is output from the output terminal DA.

Also in this case, the output signal of the D flip-flop 53 (the output signal from the output terminal E0) is the LSB, and the output signal of the HA macro 55 (the output signal of the output terminal EB) is the MSB.

Because the second counter circuit 49 is also a synchronous counter circuit, the D flip-flop 53 is synchronized with the clock signal CK, also the FA macros 54a through 54j and the HA macro 55 are synchronized with the demultiplied clock signal, and the output signals E0 through EB are output.

The counter output signal switching circuit 50 comprises an output selection circuit 60, which comprises an inverter 58 and a D flip-flop 59, and SW macros 57a through 57l, which switche the output signals of the first counter circuit 48 and the output signal of the second counter circuit 49 and outputs from output terminals D0 to DB in response to the output signal from the output selection circuit 60.

The output selection circuit 60 comprises the inverter 58 and the D flip-flop 59. The clock signal from the input terminal CK is provided to the D flip-flop 59 through the inverter 58. The output signal from the output terminal q is used as the first counter select signal (the output signal of the output terminal ES), and the inverted signal of the output terminal q is used as the second counter select signal (the output signal of the input terminal OS).

The SW macros 57a through 57l switch, in response to the first counter select signal and the second counter select signal, the output signal of the first counter circuit 48 and the output signal of the second counter circuit 49 and output to their corresponding output terminals D0 through DB.

For example, the SW macro 57b outputs the output signal of the first counter circuit 48 to the output terminal D1 when the first counter select signal is high, and outputs the output signal of the second counter circuit 49 to the output terminal D1 when the second counter select signal is high.

The SW macro 57a relating to the present embodiment is set to constantly select the output signal of the first counter circuit 48 in order to adjust the timing (i.e. to simplify the circuit configuration).

A reset signal is provided from the input terminal CL. When the clear signal becomes low, the state of the D flip-flop in the first counter circuit 48, the second counter circuit 49 and the counter output switching circuit 50 is cleared.

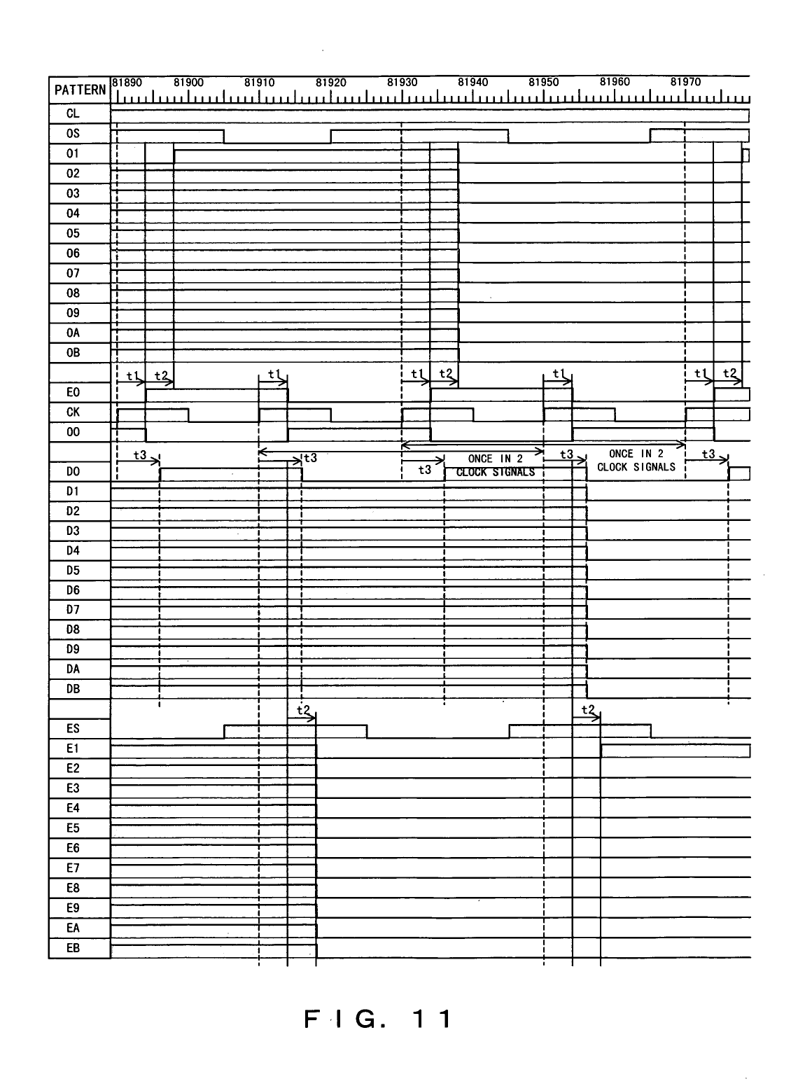

FIG. 11 is a timing chart showing some of the more important signals in the counter circuit relating to the second embodiment shown in FIG. 10.

FIG. 11 is a timing chart showing the relation of the clear signal to the input terminal CL and the clock signals to the input terminal CK of the counter circuit shown in FIG. 10, the output signals of the output terminal O0 of the HA macro 53, the FA macros 51a through 51j and the output terminals O0 through OB corresponding to the HA macro 52 in the first counter circuit 48, the output terminal E0 of the HA macro 53, the FA macros 54a through 54j and the output signals of the output terminals E0 through EB corresponding to the HA macro 55 in the second counter circuit 49, the first and the second counter select signals of the output terminals OS and ES of the output selection circuit 60 of the counter output switching circuit 50, and the output signals of the output terminals D0 through DB (the output signal of the counter circuit relating to the present embodiment) corresponding to the SW macros 57a through 57k of the counter output switching circuit 50.

In the explanation below, output terminal labels shown in FIG. 11 represent the output signals of the output terminals. For example, “signal CK” represents the output signals from the output terminal CK.

In FIG. 11, regarding the output signals O0 through OB of the first counter circuit 48, the signal O0 carries a time lag of t1 from the signal CK, and the signal O1 carries a time lag of t2 from the signal O0. Thus, the output signals O0 through OB of the first counter circuit 48 carry a total time lag of t1+t2 from the signal CK.

In a similar way, regarding the output signals E0 through EB of the second counter circuit 49, the signal E0 carries a time lag of t1 from the signal CK, and the signal E1 carries a time lag of t2 from the signal E0. Thus, the output signals E0 through EB of the second counter circuit 49 carry a total time lag of t1+t2 from the signal CK.

The output signals D0 through DB of the counter output switching circuit 50 select the first output signal when the signal OS is high, and select the second output signal when the signal ES is high. Therefore, the time lag of the output signals D0 through DB from the signal CK is t3 (<t1+t2).

The timing chart of FIG. 11, the period of each signal is exaggerated for the purposes of explanation. However, the present invention is most effective when a clock signal CK with a high frequency is employed.

As explained in FIG. 9, the carry time lag also occurs in carry up processing of D flip-flop 53, which is the LSB in the first counter circuit 48, the FA macros 51a through 51j, and the HA macro 52, which is the MSB in the first counter circuit 48, and carry up processing of the FA macros 54a through 54j and the HA macro 55 in the second counter circuit 49.

Then, the period can be reduced to the period calculated using equation (1) when the carry time lag of all bits (O0 through OB, for example) is π, the number of counters is N, and the period in which the LSB of the first counter circuit 1 can be operated is T0.

FIG. 12 is a diagram describing a configuration of the FA macros 51a through 51j and the FA macros 54a through 54j used in the counter circuit shown in FIG. 10.

The FA macros in FIG. 10 comprise an EOR gate 61, a D flip-flop 62 and an AND gate 63.

Exclusive OR operation of the signal from the input terminal CI and the signal q of a D flip-flop 62 by the EOR gate 61 divides the signal from the input terminal CI by two and the demultiplied signal is latched on the input terminal d of the D flip-flop 62. the latched signal is synchronized with the clock signal from the input terminal CK, and is output from the output terminal q.

FIG. 13 is a diagram describing a configuration of the HA macro 52 and the HA macro 55 used in the counter circuit shown in FIG. 10.

The HA macro shown in FIG. 13 comprises an EOR gate 64 and a D flip-flop 65.

Regarding the HA macro in FIG. 13, exclusive OR operation on the signal from the input terminal CI and the signal q of a D flip-flop 65 by the EOR circuit 61 divides the signal from the input terminal CI by two and the demultiplied signal is latched on the input terminal d of the D flip-flop 65. The latched signal is synchronized with the clock signal from the input terminal CK, and is output from the output terminal q.

The first counter circuit 48 and the second counter circuit 49 are ordinary synchronous counter circuits, each comprising FA macros 51 as shown in FIG. 12, HA macros 52 as shown in FIG. 13 and D flip-flops 53 and 56. Therefore, the explanation of their detailed operations is omitted.

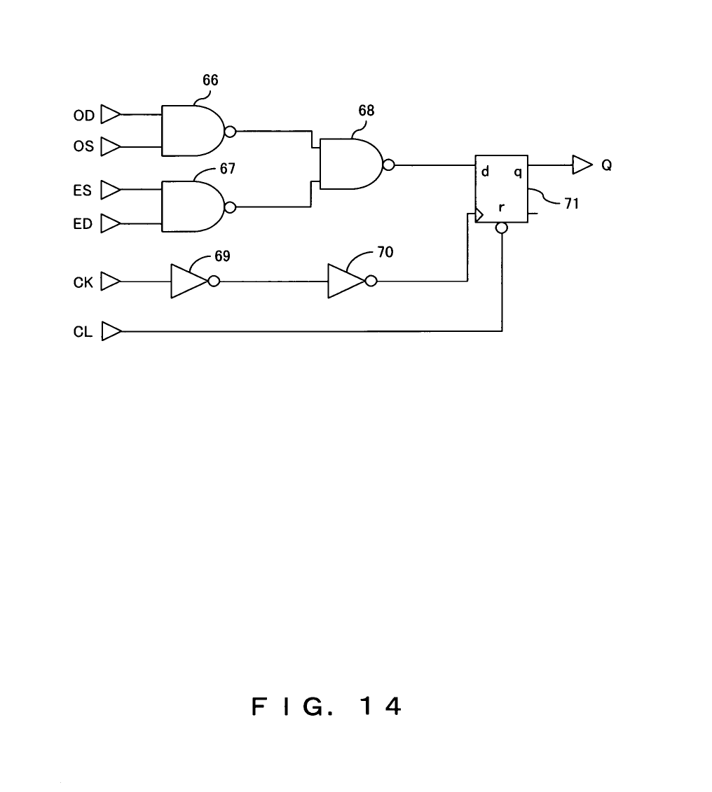

FIG. 14 is a diagram describing a configuration of the SW macros 57a through 57k used in the counter circuit shown in FIG. 10.

The SW macro shown in FIG. 14 comprises NAND gates 66 through 68, inverters 69 and 70 and a D flip-flop 71. In regards to the NAND gate 66, the output signal of the first counter circuit 48 is provided to an input terminal OD, and the first counter select signal of the output selection circuit 60 is provided to an input terminal OS. In regards to NAND gate 67, the output signal of the second counter circuit 49 is input to an input terminal ED, and the second counter select signal of the output selection circuit 60 is input to an input terminal ES.

Accordingly, the NAND gates 66 through 68 switch the output signal of the first counter circuit 48 and the output signal of the second counter circuit 49, and output to D flip-flop 71, in response to the first counter select signal or the second counter select signal of the output selection circuit 60. For example, a high-level signal is input to the input terminal d of the D flip-flop 71 when the first counter select signal of the output selection circuit 60 is high and the output signal of the first counter circuit 48 is also high. A high-level signal is also input to the input terminal d of the D flip-flop 71 when the second counter select signal of the output selection circuit 60 is high and the output signal of the second counter circuit 49 is also high.

The inverters 69 and 70 are inserted so as to adjust the time lag caused by the NAND gates 66 through 68.

By the operation above, the SW macro selects the output signal from the first counter circuit 48 provided to the input terminal OD and latches and outputs a signal in accordance with the clock signal provided to the input terminal CK when the first counter select signal from the output selection circuit 60, provided to the input terminal OS, is high. The SW macro selects the output signal from the second counter circuit 49 provided to the input terminal ED and latches and outputs a signal in accordance with the clock signal provided to the input terminal CK when the second counter select signal from the output selection circuit 60, provided to the input terminal ES, is high.

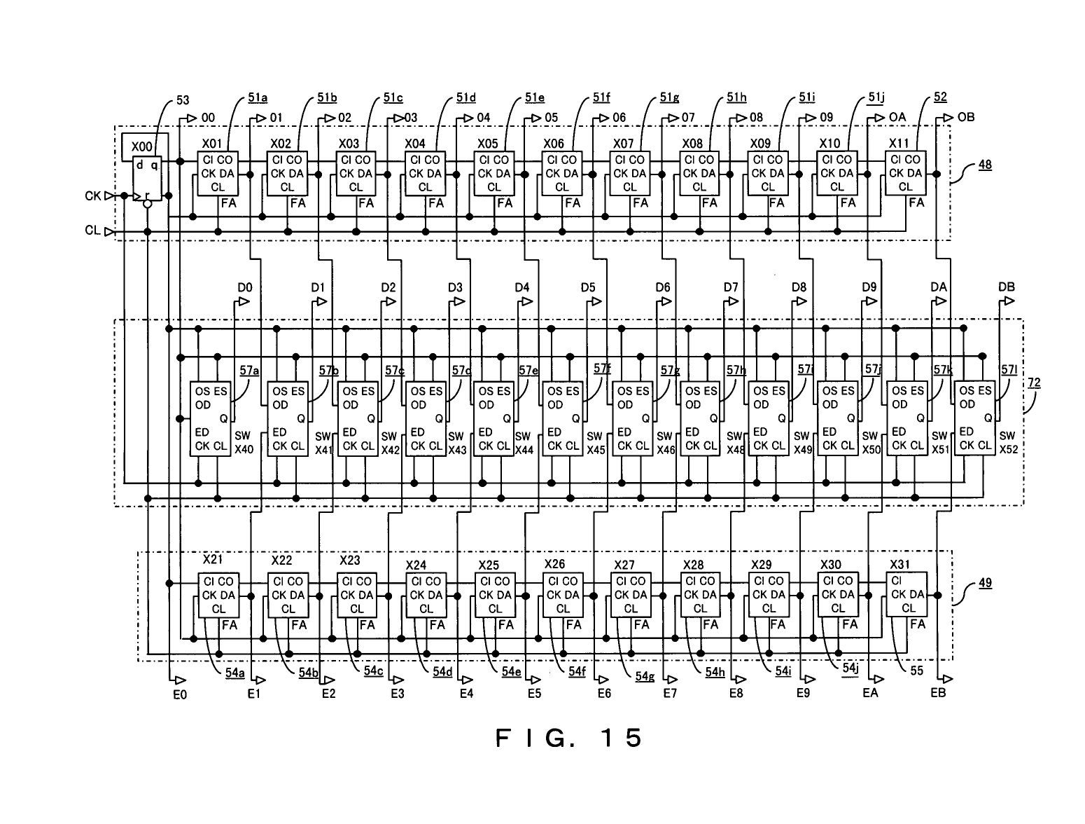

FIG. 15 is a diagram describing a configuration of a variation of the counter circuit relating to the second embodiment shown in FIG. 10.

The counter circuit shown in FIG. 15 is an example of a configuration in which the function of the output selection circuit 60 in the counter circuit, shown in FIG. 10, is performed by the D flip-flop 53 in the first counter circuit 48, and it comprises the first counter circuit 48, which counts the input clock signal from the input terminal CK, the second counter circuit 49, which also counts the input clock signal from the input terminal CK, and a counter output switching circuit 72, which switches between the output signal of the first counter circuit 48 and the output signal of the second counter circuit 49.

Then, the first counter select signal OS and the second counter select signal ES in the counter output switching circuit 50 shown in FIG. 10 are the output signals from the d terminal and the output from the q terminal, respectively, of the D flip-flop 53 in the first counter circuit 48.

Consequently, the configuration of the counter circuit is the same as the counter circuit shown in FIG. 10 except that the first counter select signal OS and the second counter select signal ES are generated by the D flip-flop. Therefore, an explanation of its operation is omitted because its operation is the same.

By the configuration explained above, the function of the output selection circuit 60 shown in FIG. 10 is included in the D flip-flop 53. Compared to the counter circuit shown in FIG. 10, the circuit can be simplified.

As explained above, a plurality of counter circuits are implemented so that they have a designated phase difference between each other. By selectively switching between the output of each counter circuit, it is possible to greatly reduce the influence of carry time lag on each counter circuit.

The above explanations described the case where two counter circuits are used and the case where four circuits are used. However, the number of counter circuits is not limited to two or four. That is, similar effects to the effect described in the embodiment can be obtained by the use of two or more counter circuits. The number of counter circuits used can be either an odd number or even number.

For example, when N counter circuits (N is an integer greater than 2) are used, and when said counter circuits are operated so that each counter circuit has a designated phase difference of (2π/N[rad], for example), a given counter circuit performs counting with leading phase shifted by 2π/N[rad]. By selecting the output of a counter circuit, that has finished counting, its carry time lag can be reduced by a factor of 1/N.

For a given number of bits, high-speed counting with a frequency N times higher is possible. At lower frequencies (e.g. 1/N frequency), it is possible to increase the number of bits of the counter, which reduces the carry time lag.

What is claimed is:

1. A counter circuit comprising:
a plurality of count units, which count the input signal and output the count result;
a phase control unit, which controls a plurality of the count units so that they comprise a designated phase difference from each other; and
a counter output switching unit, which switches from the output of any one count unit, controlled to have a designated phase difference by the phase control unit, to the output of the other count units which have a leading phase from the one count unit.

2. The counter circuit according to claim 1, further comprising an output selection unit, which generates and specifies the timing to serially select the count unit having the leading phase from a plurality of count unit in response to the input signal, wherein the counter output switching unit switches, in response to the signal from the output selection unit, between the output of any one counter unit and the output of the specifies counter unit.

3. The counter circuit according to claim 2, wherein the output selection unit generates the timing with more than two signals comprising a designated phase difference generated from the input signal.

4. The counter circuit according to claims 3, wherein the counter circuit comprises a plurality of flip-flops.

5. The counter circuit according to claim 4, wherein any one of the counter circuits and the other counter circuit shares at least one-bit or more from the LSB

6. The counter circuit according to claim 4, wherein the counter circuit, comprising a plurality of flip-flops is an asynchronous counter circuit.

7. The counter circuit according to claim 4, wherein the counter circuit, comprising a plurality of flip-flops is a synchronous counter circuit.

8. A counter circuit, comprising:
a first counter circuit, which counts the input signal and outputs the count result;
a second counter circuit, which counts the input signal and outputs the count result;
a phase control circuit, which controls a phase so that the second counter circuit has a phase difference of π [rad] from the first counter circuit; and
a counter output switching unit, which switches between the output of the first counter circuit and the output of the second counter circuit with the leading phase of π [rad] by the phase control circuit at a designated timing.

9. The counter circuit according to claim 8, further comprising an output selection circuit, which generates the output selection signal selecting the first counter circuit or the second counter circuit based on the input clock signal, wherein the count output switching circuit switches between the output signal of the first counter circuit and the output signal of the second counter circuit in response to the output selection signal from the output selection circuit and outputs the switched output signal.

10. A counter circuit, comprising:
a first counter circuit, which counts the input signal and outputs the count result;
a second counter circuit, which counts the input signal and outputs the count result;
a third counter circuit, which counts the input signal and outputs the count result;
a fourth counter circuit, which counts the input signal and outputs the count result;
a phase control circuit, which controls a phase so that each of the first and the second counter circuits, the second and the third counter circuits, the third and the fourth counter circuits, and the fourth and the first counter circuits have a leading phase of π/2[rad]; and
a counter output switching unit, which switches the output of the first counter circuit, the second counter circuit, the third counter circuit, and the fourth counter circuit with a leading phase of π/2[rad] by the phase control circuit at a designated timing.

11. The counter circuit according to claim 10, further comprising an output selection circuit generating the output selection signal, which selects from the first counter circuit, the second counter circuit, the third counter circuit and the fourth counter circuit based on the input clock signal, wherein the count output switching circuit switches between the output signal of the first counter circuit, the output signal of the second counter circuit, the output signal of the third counter circuit and the output signal of the fourth counter circuit in response to the output selection signal from the output selection circuit, and output the switched output signal.

12. A counting method in the counter circuit comprising a plurality of count units, which counts the input signal and outputs the count result, performs:
a phase control process of taking control so that a plurality of the count units have a designated phase difference from each other; and
a counter output switching process of switching between the output of any one of the count units controlled to have a designated phase difference by the phase control process and the output of the other count units with a leading phase from the one count unit.

13. The counting method according to claim 12, further performing a output selection process of generating and specifying the timing to serially select the count unit with the leading phase from a plurality of count units in response to the input signal, wherein the count output switching process switches process between the output of any one of the count units and the output of the specified count unit in response to the information from the output selection unit.

14. A counter circuit, comprising:
a count unit, which counts the input signal and outputs the count result with a designated phase difference from the input signal; and
a counter output selection unit, which selects only a output of any one count unit among a plurality of the count units and serially switches to the output of the other count units with the phase difference from the one count unit.

15. A counter circuit, comprising:
a plurality of count units, which counts the input signal and outputs the count result;
a phase control unit, which controls the parallel distribution process in which the input signal is provided to a plurality of count units so that a plurality of count units have a designated leading phase from each other and also controls the count process in which the other count units count the value to be output after the count result while the one count unit outputs the count result; and
a counter output switching unit, which switches the output from the output of the one count unit controlled to have a designated phase difference by the phase control unit to the output of the other count units comprising a leading phase from the one count unit.

16. A counter circuit, comprising:
a plurality of count means, which count the input signal and output the count result;
phase control means, which controls a plurality of the count means so that they have a designated phase difference from each other; and
counter output switching means, which switches from the output of any one count means, controlled to comprise a designated phase difference by the phase control means, to the output of the other count means, comprising a leading phase of the one count means.

17. A counter circuit, comprising:
a first counter circuit, which counts the input signal and outputs the count result;
a second counter circuit, which counts the input signal and outputs the count result;
a phase control circuit controlling the phase so that the second counter circuit has a phase difference of π [rad] from the first counter circuit; and
a counter output switching circuit for switching from the output of the first counter circuit to the output of the second counter circuit with the leading phase of π [rad] by the phase control circuit at a designated timing.

18. A counter circuit, comprising:
a first counter circuit, which counts the input signal and outputs the count result;
a second counter circuit, which counts the input signal and outputs the count result;
a third counter circuit, which counts the input signal and outputs the count result;
a fourth counter circuit, which counts the input signal and outputs the count result;
a phase control circuit, which controls the phase so that each of the first and the second counter circuits, the second and the third counter circuits, the third and the fourth counter circuits, and the fourth and the first counter circuits have a leading phase of π/2[rad]; and
a counter output switching circuit, which switches the output of the first counter circuit, the second counter circuit, the third counter circuit, and the fourth counter circuit, with a leading phase of π/2[rad] set by the phase control circuit at a designated timing.

19. A counting method in the counter circuit comprising a plurality of count means, which counts the input signal and outputs the count result, comprising:
a phase control process of controlling the phase so that a plurality of the count means have a designated phase difference from each other; and
a counter output switching process of switching between the output of any one of the count means controlled to have a designated phase difference by the phase control process and the output of the other count means with a leading phase from the one count means.

20. A counter circuit, comprising:
count means, which counts the input signal and outputs the count result with a designated phase difference from each other; and
counter output selection means, which selects only the output of any one count means among a plurality of the count means and serially switches to the output of the other count means with a leading phase from the one count means.

21. A counter circuit, comprising:
a plurality of count means, which counts the input signal and outputs the count result;
a phase control means, which controls the parallel distribution process in which the input signal is provided to a plurality of the count means so that a plurality of the count means have a designated leading phase from each other and also controls the count process in which the other count means count the value to be output after the count result while one count means outputs the count result; and
a counter output switching means, which switches the output from the output of the one count means controlled to have a designated phase difference by the phase control means to the output of the other count means with a leading phase from the one count means.
